(19) United States
(12) Patent Application Publication
(10) Pub. No.: US 2009/0027851 A1
(43) Pub. Date: Jan. 29, 2009

(54) Computing device cooling system access assembly

(76) Inventors: Paul J. Doczy, Cypress, TX (US); Mark S. Tracy, Tomball, TX (US); Earl W. Moore, Cypress, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/881,376

(22) Filed: Jul. 26, 2007

(51) Int. Cl. H05K 7/20

(52) U.S. Cl. 361/688

(57) ABSTRACT

A computing device comprising a heat exchanger and an access door disposed on a housing of the computing device and the access door aligned with at least a portion of the heat exchanger to facilitate access to the heat exchanger.

### BACKGROUND

Computing devices, such as laptop or notebook computers, comprise cooling systems to dissipate thermal energy generated by the computing device. Such cooling systems oftentimes include an air circulation device to force cooling air through a heat exchanger to dissipate heat from one or more computer operational components. However, in operation, dust and other unwanted particulates collect inside the cooling system and, specifically, on or inside the heat exchanger, thereby decreasing the efficiency of heat dissipation by the heat exchanger.

### BRIEF DESCRIPTION OF THE DRAWINGS

FIG. 1 is a diagram illustrating a computing device in which an embodiment of a cooling system access assembly is employed to advantage; and

FIG. 2 is diagram of a section view of the computing device of FIG. 1 taken along the line 2-2 of FIG. 1.

### DETAILED DESCRIPTION OF THE DRAWINGS

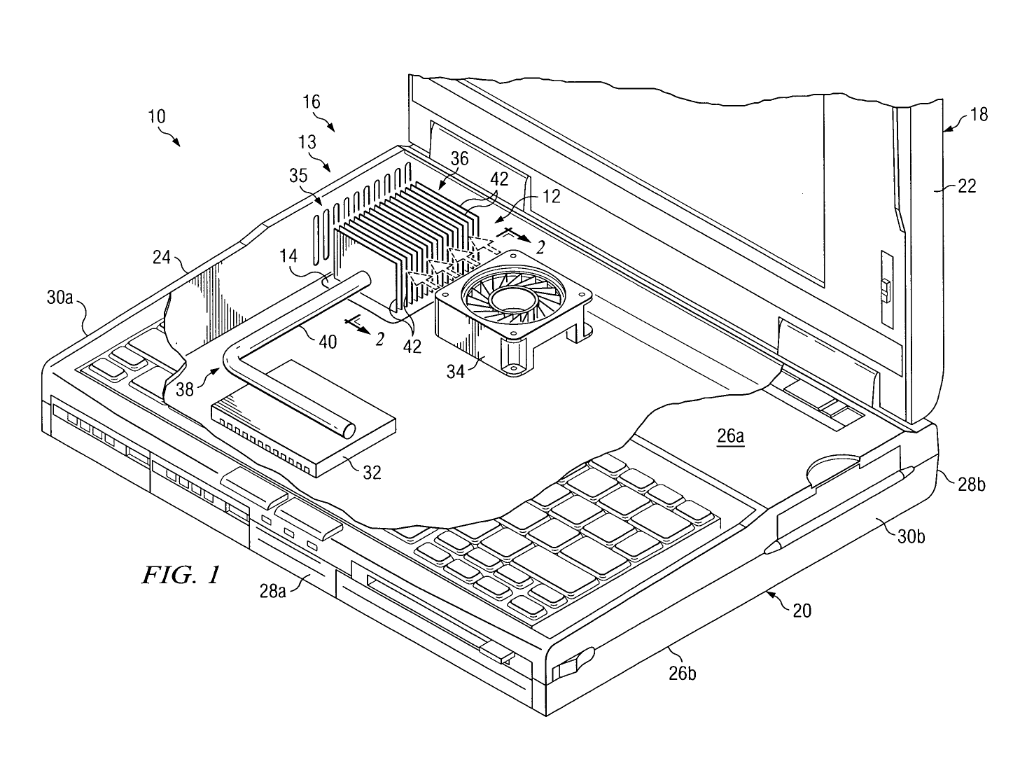

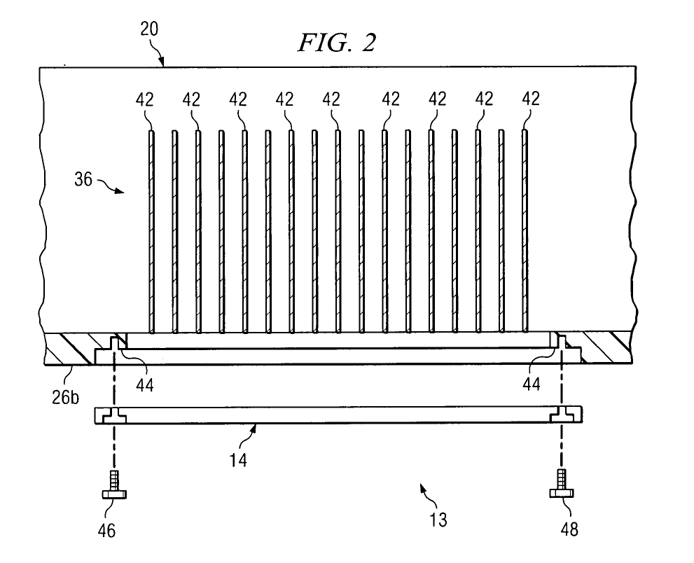

Various embodiments and the advantages thereof are best understood by referring to FIGS. 1 and 2, like numerals being used for like and corresponding parts of the various drawings.

FIG. 1 is a diagram illustrating a computing device 10 comprising a cooling system 12 in which an embodiment of an access assembly 13 is employed to advantage. In the embodiment illustrated in FIG. 1, computing device 10 comprises a laptop or notebook computer 16; however, it should be understood that computing device 10 may comprise any type of computing device such as, but not limited to, a tablet personal computer, a personal digital assistant, a desktop computer or any other type of portable or non-portable computing device. In the embodiment illustrated in FIG. 1, computing device 10 comprises a display member 18 rotatably coupled to a base member 20. Display member 18 and base member 20 each comprise a housing 22 and 24, respectively, formed having a number walls. For example, housing 24 comprises a top wall/working surface 26a, a bottom wall 26b, a front wall 28a, a rear wall 28b and a pair of side walls 30a and 30b.

In the embodiment illustrated in FIG. 1, cooling system 12 is disposed within housing 24 of base member 20 and is configured to dissipate and/or otherwise remove thermal energy from an internal area of base member 20, such as dissipating thermal energy generated by one or more computer operational components 32 disposed within housing 24. It should be understood that all or a portion of cooling system 12 may be otherwise located (e.g., within display member 18 of computing device 10 or within both display member 18 and base member 20).

In the embodiment illustrated in FIG. 1, cooling system 12 comprises an airflow device or cooling fan 34, a heat dissipating element 35 configured as a heat exchanger 36, and a heat transport element 38 thermally coupling at least one computer operational component 32 to heat exchanger 36. Heat transport element 38 may comprise any type of thermally conductive element for transferring heat from operational component 34 to heat exchanger 36. For example, in some embodiments, heat transport element 38 comprises a heat pipe 40 filled with a vaporizable liquid to increase heat transfer performance. In the embodiment illustrated in FIG. 1, heat exchanger 36 comprises a plurality of fins 42 to facilitate thermal energy dissipation from heat exchanger 36. In operation, cooling air is directed from cooling fan 34 through fins 42 of heat exchanger 36 to dissipate thermal energy generated by operational component(s) 32 and/or otherwise dissipate thermal energy from within housing 24.

In the embodiment illustrated in FIG. 1, cooling system access assembly 13 comprises a door 14 to provide access to the interior area of housing 24 and aligned with heat exchanger 36 to facilitate access to heat exchanger 36. According to some embodiments, access door 14 is openable relative to at least one of the plurality of walls 26a, 26b, 28a, 28b and sidewalls 30a and 30b to facilitate access to heat exchanger 36 through the wall that the access door is coupled thereto. For example, in the embodiment illustrated in FIG. 1, access door 14 is disposed on bottom wall 26b adjacent to heat exchanger 36 to facilitate access to heat exchanger 36 through wall 26b; however, it should be understood that access door 14 may be otherwise disposed adjacent to heat exchanger 36 (e.g., top wall 26a, front wall 28a, rear wall 28b and/or sidewalls 30a and/or 30b). In operation, access door 14 is openable and/or removable from bottom wall 26b to facilitate direct access to fins 42 of heat exchanger 36 to enable extraction of impurities such as sand, dust, hair, and/or any other debris deposited on and/or between fins 42 resulting from the flow of cooling air through heat exchanger 36.

In the embodiment illustrated in FIG. 1, access door 14 is sized such that a perimeter of access door 14 is located substantially equal to or greater than the locations/dimensions of fins 42 such that upon removal of access door 14 from bottom wall 26b, access to each fin 42 is provided to facilitate the extraction of impurities from heat exchanger 36. According to some embodiments, access door 14 may be aligned with only a portion of fins 42 and/or multiple access doors 14 may be aligned with different portions of heat exchanger 36 to facilitate access thereto.

FIG. 2 is a diagram of a section view of computing device 10 of FIG. 1 taken along the line 2-2 of FIG. 1. In the embodiment illustrated in FIG. 2, access door 14 is coupleable to bottom wall 26b of housing 20 via a plurality of screws 46 and 48. According to some embodiments, access door 14 is detachable from housing 24; however, it should be understood that access door may be otherwise coupled to housing 24 (e.g., pivotably coupled to housing 24 via a hinge, etc.). According to some embodiments, bottom wall 26b comprises a recess 44 to receive access door 14 to enable access door 14 to rest flush (flush or substantially flush) with bottom wall 26b. However, it should be understood that the interface between access door 14 and housing 24 may be otherwise configured.

Thus embodiments of assembly 13 provide a cooling system access door 14 to facilitate direct access to heat exchanger 36 to enable removal of debris, sand, dust, hair deposited on and/or between fins 42 as a result of the flow of cooling air through heat exchanger 36.

1. A computing device, comprising;
a housing comprising at least one surface;
a heat exchanger, having at least one fin disposed thereupon, the heat exchanger disposed in, on, or about the housing; and
an access door disposed in, on, or about the at least one surface;
wherein the access door is proximate, and commensurate in size with, the at least one fin disposed upon the heat exchanger, thereby providing unobstructed access to the at least one fin.

2. The computing device of claim 1, wherein the access door is pivotably connected to the at least one surface.

3. (canceled)

4. The computing device of claim 1, wherein the access door is sized to correspond to a size of the heat exchanger.

5. The computing device of claim 1, wherein the access door is detachably connected to the at least one surface.

6. A method of manufacturing a computing device, comprising:
providing a housing comprising at least one surface;
disposing a heat exchanger having at least one fin disposed thereupon within the housing; and
disposing an access door in, on, or about the at least one surface of the housing, wherein the access door is proximate and commensurate in size with the at least one fin disposed upon the heat exchanger, thereby providing unobstructed access to the at least one fin.

7. The method of claim 6, wherein the access door is pivotably connected to the at least one surface of the housing.

8. (canceled)

9. The method of claim 6, wherein the access door is sized to correspond to a size of the heat exchanger.

10. The method of claim 6, wherein the access door is pivotably connected to the at least one surface of the housing.

11. A computing device, comprising:
means for housing the computing device, the means comprising at least one surface;
means for dissipating heat from the housing means, the means for dissipating heat having at least one fin disposed thereupon; and
means, disposed in, on, or about the at least one surface, proximate, and commensurate in size with the at least one fin, to provide unobstructed access to the at least one fin of the heat dissipating means.

12. The computing device of claim 11, wherein the accessing means is pivotably connected to the at least one surface of the housing means.

13. (canceled)

14. (canceled)

15. The computing device of claim 11, wherein the accessing means is detachably connected to the at least one surface of the housing means.

16. A computing device, comprising:
a housing comprising at least two opposed surfaces;
a heat exchanger having at least one fin disposed thereupon, disposed between the at least two opposed surfaces; and
an access door detachably attached to at least one of the at least two opposed surfaces, wherein the access door is proximate and commensurate in size to the at least one fin, and wherein, when the access door is detached, unobstructed access to the at least one fin is provided, and wherein all or a portion of the heat exchanger remains partially or completely disposed between the two opposed surfaces at all times.

17. The computing device of claim 16, wherein the access door is detachably attached to one of the at least two opposed surfaces using one or more hinges.

18. (canceled)

19. The computing device of claim 1, wherein the computing device is embodied as a laptop computer.

20. The computing device of claim 11, wherein the computing device is embodied as a laptop computer.
